(19) United States
(12) Patent Application Publication
(10) Pub. No.: US 2007/0147120 A1
(43) Pub. Date: Jun. 28, 2007

(54) Page buffer and related reading method

(76) Inventor: Tae-Young Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/513,162

(22) Filed: Aug. 31, 2006

(30) Foreign Application Priority Data
Dec. 28, 2005 (KR) 2005-131851

(51) Int. Cl. G11C 16/04; G11C 7/10; G11C 11/34

(52) U.S. Cl. 365/185.17; 365/189.05; 365/185.2

(57) ABSTRACT

A page buffer and a reading method comprising a unitary operation adapted to execute either a normal read operation or a copyback read operation using a page buffer are disclosed. The unitary operation comprises initializing a latch to store a first logic value; sensing a voltage level corresponding to a programming state of a selected memory cell; and selectively storing a second logic value in the latch in response to the sensed voltage level, wherein the page buffer enters a programming operation mode when the second logic value is stored in the latch.

### BACKGROUND

1. Field of the Invention

Embodiments of the invention relate to a non-volatile memory device and related reading method. In particular, embodiments of the invention relate to a page buffer adapted for use in a flash memory device and a related reading method.

This application claims priority to Korean Patent Application No. 2005-131851, filed Dec. 28, 2005, the subject matter of which is hereby incorporated by reference in its entirety.

2. Discussion of Related Art

A semiconductor memory device is generally categorized as either a volatile or a non-volatile memory device. Volatile memory devices are classified into dynamic random access memories (DRAMs) and static random access memories (SRAMs). A volatile semiconductor device loses its stored data when its power supply is interrupted, while a non-volatile memory device retains its stored data even when its power supply is interrupted. Thus, non-volatile memories are widely used to store data in applications in which data retention is required regardless of power supply interruptions. Mask read-only memories (MROMs), programmable read-only memories (PROMs), erasable programmable read-only memories (EPROMs), and electrically erasable programmable read-only memories (EEPROMs) are each non-volatile memories.

However, it is difficult to rewrite stored data in MROMs, PROMs, and EPROMs because read and write operations cannot be freely performed by normal users. On the other hand, EEPROMs are increasingly being used in systems where system programming requires continuous updating, and in auxiliary memory devices. In particular, it is very advantageous to use a flash EEPROM as a mass storage device because the integration density of a flash EEPROM is higher than the integration density of a conventional EEPROM. Among flash EEPROMs, NAND-type flash EEPROM (which will be referred to hereinafter as “NAND flash memory”) has a much higher integration density than NOR-type or AND-type flash EEPROM.

A NAND flash memory device having flash EEPROM cells is illustrated in Figure (FIG.) 1. The flash memory device includes a memory cell array 10, a page buffer circuit 20, and a row decoder circuit 30. Rows of memory cell array 10 are driven by row decoder circuit 30, and columns of memory cell array 10 are driven by page buffer circuit 20. Memory cell array 10 comprises a plurality of blocks, each of which includes a plurality of strings. In addition, each of the strings includes a plurality of flash memory cells connected in series, wherein each of the memory cells includes a floating gate and a control gate. In each of the memory cells, programming (injecting electrons into a floating gate) and erasing (ejecting electrons from the floating gate) are performed through Fowler-Nordheim (FN) tunneling. As used herein, when a selected memory cell is said to be “programmed,” it means that electrons have been injected into the floating gate the selected memory cell, and when the selected memory cell is said to be “erased,” it means that electrons have been ejected from the floating gate of the selected memory cell. Injecting electrons into a floating gate and ejecting electrons from a floating gate each cause the threshold voltage of the selected memory cell to vary. A memory cell that is erased has a negative threshold voltage (e.g., −3 volt) because electrons have been discharged from its floating gate into a bulk, or a source or drain, of the memory cell. A memory cell that is erased is also referred to herein as being “ON.” On the other hand, a memory cell that is programmed has a positive threshold voltage (e.g., about +1 volt) because electrons have been injected into the floating gate. A memory cell that is programmed is also referred to herein as being “OFF.”

Page buffer circuit 20 can perform programming and read operations on each memory cell. A read operation is performed to determine whether a selected memory cell is programmed or erased. Because of ever-increasing demands for flash memory devices that can perform multiple functions (i.e., multi-functional flash memory devices), page buffer circuit 20 can perform additional functions, such as a page copyback function. In the page copyback function, data stored in a first page is copied into a second page through page buffer circuit 20 without outputting the data stored in the first page.

Page buffer circuit 20 includes a plurality of page buffers, and each of the page buffers includes a latch. Each of the page buffers can store data in a latch during a normal read operation or a read operation for a page copyback operation (which will be referred to hereinafter as a “copyback read operation”), wherein the data is sensed from a selected memory cell using a sense node. Each of the page buffers can also store data in a latch during a normal program operation, wherein the data will subsequently be stored into a memory cell. Storing data in a latch is controlled by a control logic block (not shown) disposed outside of the page buffer. Each of the latches stores data using a power supply voltage as a source.

However, a characteristic of the page buffers is that, when the same data value is read during a normal read operation and during a copyback read operation, wherein each is performed in the same page buffer (i.e., data is read out from the same page), the data value latched in the page buffer during a copyback read operation has a logic value opposite that of the data value latched in the page buffer during a normal read operation. The purpose of the preceding characteristic is to prevent the page buffer from entering a program-inhibit operation mode in accordance with a data value read from a memory cell (i.e., in accordance with the programming state of a memory cell). Entering the program-inhibit operation mode in accordance with a data value read from a memory cell needs to be prevented because a page buffer in a program-inhibit operation mode is incapable of programming data read from a first page during a copyback read operation into a second page. Accordingly, when data is read during a copyback read operation, the logic value of the data read is inverted along the opposite electrical path compared to a normal read operation. Such a read operation is referred to as an inverse-read operation. When an inverse-read operation is not performed, a check bit or the like is additionally required in order to check whether the data value read during a copyback read operation is an inverted version of the data value that would be read during a corresponding normal read operation. Thus, the configuration of and method for controlling a page buffer becomes complex.

### SUMMARY OF THE INVENTION

Embodiments of the invention provide a page buffer and a related reading method.

In one embodiment, the invention provides a reading method comprising a unitary operation adapted to execute either a normal read operation or a copyback read operation using a page buffer. The unitary operation comprises initializing a latch to store a first logic value; sensing a voltage level corresponding to a programming state of a selected memory cell; and selectively storing a second logic value in the latch in response to the sensed voltage level, wherein the page buffer enters a programming operation mode when the second logic value is stored in the latch.

In another embodiment, the invention provides a method for performing a copyback read operation in a page buffer comprising initializing a latch to store a first logic value; sensing a voltage level corresponding to a programming state of a selected memory cell; and selectively storing a second logic value in the latch in response to the sensed voltage level, wherein the page buffer enters a programming operation mode when the second logic value is stored in the latch.

In another embodiment, the invention provides a page buffer adapted to perform either a normal read operation or a copyback read operation using a unitary operation. The page buffer comprises a bitline select and bias unit adapted to select a bitline corresponding to a selected memory cell; a precharge unit adapted to precharge the bitline; and a sense and latch unit adapted to sense a level of a voltage apparent on the bitline and store a logic value in a latch in response to the sensed voltage level, wherein the latch is initialized to store a first logic value during each of the normal read operation and the copyback read operation, and wherein the value stored in the latch changes from the first logic value to a second logic value if the sensed voltage level indicates that the selected memory cell is programmed.

### BRIEF DESCRIPTION OF THE DRAWINGS

Embodiments of the invention will be described herein with reference to the accompanying drawings, in which like reference symbols refer to like or similar elements throughout. In the drawings:

FIG. 1 is a block diagram of a conventional flash memory device;

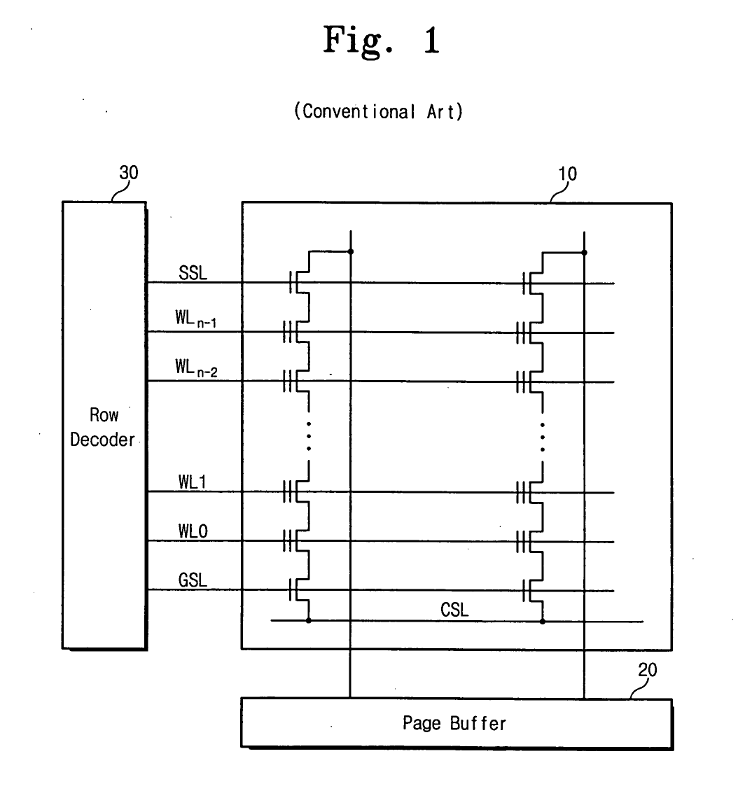

FIG. 2 is a circuit diagram of a page buffer in accordance with an embodiment of the invention; and,

FIG. 3 is a timing diagram for an operation of the page buffer illustrated in FIG. 2.

### DESCRIPTION OF EMBODIMENTS

While the present invention will be described herein with reference to a page buffer of a flash memory device adapted to perform both a normal read operation and a copyback read operation using a single latch, the page buffer referred to is merely exemplary, so various modifications and alternatives may be made therein (or used) without departing from the scope of the invention as defined by the accompanying claims.

A flash memory device comprises a memory cell array adapted to store data. In the memory cell array, a plurality of cell strings (i.e., NAND strings) are arranged such that they are connected to corresponding bitlines. As is well known, each cell string comprises a string select transistor connected to a corresponding bitline, a ground select transistor connected to a common source line, and memory cells disposed serially between the string select transistor and the ground select transistor.

A plurality of bitline pairs BLe, BLo is connected to the memory cell array, and each of a plurality of page buffers is electrically connected to a respective bitline pair. Each of the page buffers is adapted to function as a sense amplifier during a normal read operation or a copyback read operation, and is also adapted to function as a driver adapted to drive a bitline in accordance with the data to be programmed during a programming operation. Since all of the page buffers of the plurality of page buffers disposed in a flash memory device have the same configuration, for convenience of description, only one page buffer (e.g., a page buffer 200) will be illustrated herein.

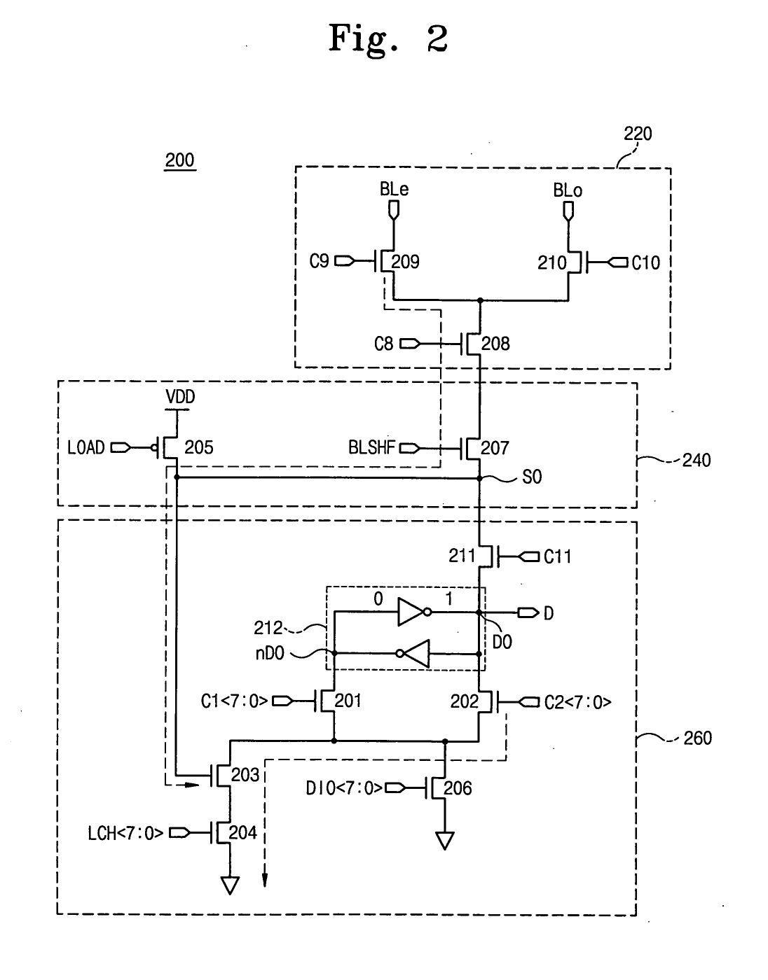

FIG. 2 illustrates a page buffer 200 in accordance with an embodiment of the invention. Page buffer 200 comprises a bitline select and bias unit 220, a precharge unit 240, and a sense and latch unit 260.

Bitline select and bias unit 220 selects a bitline BLe or BLo to be sensed during a normal read operation or a copyback read operation. Precharge unit 240 precharges the selected bitline BLe or BLo and precharges a sense node S0 before performing the normal read operation or copyback read operation. Sense node S0 is disposed in precharge unit 240 and is connected to sense and latch unit 260. Sense and latch unit 260 comprises a latch 212 adapted to store a data value, and the data value may selectively change in response to a voltage apparent on sense node S0. A logic value is apparent at a node D0 of latch 212 (node D0 will be referred to hereinafter as “latch node” D0), and the logic value apparent at latch node D0 may vary in accordance with the level of the voltage apparent on sense node S0. Latch node D0 is adapted to output the logic value apparent at latch node D0 during a normal read operation, so latch node D0 is adapted to function as an output node.

Sense and latch unit 260 performs both a normal read operation and a copyback read operation along the same electrical path of sense and latch unit 260. For that reason, when a read operation is performed, latch 212 is initialized (during a page buffer setting period of the read operation) such that a logic value of “1” is apparent at latch node D0 regardless of whether the read operation is a normal read operation or a copyback read operation. When a logic value of “1” is apparent on latch node D0, page buffer 200 is set to a program-inhibit operation mode. If a selected memory cell (i.e., the memory cell being read during the read operation) is programmed, the level of the voltage apparent on sense node S0 during a sense and latch period of a read operation causes the state of latch 212 to change from the initialized state, in which a logic value of “1” is apparent on latch node D0, to a state in which a logic value of “0” is apparent on latch node D0. When a logic value of “0” is apparent on latch node D0, page buffer 200 is set to a programming operation mode. Thus, page buffer 200 may be able to program the data read during a copyback read operation. If data is read through a normal read operation, corresponding data may be output to the exterior.

Because the normal read operation and the copyback read operation are performed along the same electrical path in page buffer 200, data read from a selected memory cell during the normal read operation will have the same logic value as data read from the selected memory cell during the copyback read operation when the selected memory cell has the same programming state (i.e., programmed or erased) during each of those operations. Additionally, the logic value of data stored in latch 212 during the normal read operation will be the same as the logic value of data stored in latch 212 at corresponding stages in the copyback read operation, wherein each of the preceding operations is performed on a selected memory cell having the same programming state during each of those operations. Therefore, it is unnecessary to perform an inverse-read operation or check whether a data bit is inverted using an additional check bit in page buffer 200. As a result, controlling page buffer 200 is simplified.

The configuration of page buffer 200 will now be described in more detail.

Bitline select and bias unit 220 comprises three NMOS transistors, which are NMOS transistors 208, 209, and 210. Each of NMOS transistors 208, 209, and 210 is connected to corresponding bitlines BLe and BLo. NMOS transistors 209 and 210 are each adapted to select a bitline, on which a read operation will be performed, in response to bitline select signals C9 and C10, respectively. Bitline select signals C9 and C10 are applied to gates of NMOS transistors 209 and 210, respectively. A selected bitline is electrically connected to precharge unit 240 and sense and latch unit 260. For convenience of description, it will be assumed hereinafter that bitline BLe of bitlines BLe and BLo connected to page buffer 200 is the selected bitline and may be referred to hereinafter as selected bitline BLe, wherein bitline BLe is the 2 n^{th} bitline of a corresponding memory cell array and n is a positive integer.

NMOS transistor 208 is disposed between drains of NMOS transistors 209 and 210, and precharge unit 240. Because of NMOS transistor 208, a voltage higher than a power supply voltage VDD is not directly applied to page buffer 200 through the selected bitline (e.g., selected bitline BLe). As is well known, page buffer 200 is a low-voltage circuit that operates at power supply voltage VDD. Therefore, when a voltage higher than power supply voltage VDD is directly applied to page buffer 200, the low-voltage transistors that page buffer 200 comprises may be damaged because of a breakdown effect. For this reason, each of NMOS transistors 208, 209, and 210 of bitline select and bias unit 220 is a high-voltage transistor that is durable against a high voltage. Each of NMOS transistors 208, 209, and 210 is a high-voltage transistor having a breakdown voltage of, for example, 28 volts.

Precharge unit 240 comprises a PMOS transistor 205 and a NMOS transistor 207, which are each low-voltage transistors having a breakdown voltage of, for example, 7 volts. PMOS transistor 205 is disposed between power supply voltage VDD and sense node S0, and is turned ON and OFF in response to a precharge control signal LOAD. When PMOS transistor 205 is turned ON, bitline BLe is precharged to a predetermined level by power supply voltage VDD. NMOS transistor 207 is disposed between NMOS transistor 208 disposed in select circuit 220 and sense node S0. NMOS transistor 207 is turned ON and OFF in response to a shutoff control signal BLSHF. NMOS transistor 207 is adapted to electrically insulate bitline BLe from sense node S0. Therefore, NMOS transistor 207 is often called a shutoff transistor.

To perform a read operation, selected bitline BLe is precharged to a predetermined voltage level, then a read voltage Vread (e.g., +4.5 volts) is applied to unselected wordlines, and a voltage of 0 volts is applied to a selected wordline. As a result, development of selected bitline BLe begins. As used herein, the term “develop” (or its various other forms) used with reference to a bitline (e.g., “developing the selected bitline”) refers to a process of allowing the level of the voltage apparent on the bitline to either remain at a precharged level or drop to a logic low level in accordance with the programming state of the selected memory cell. If, during the develop period, the programming state of a selected memory cell connected to the selected wordline is programmed (i.e., the selected memory cell is programmed, or OFF), then the voltage apparent on selected bitline BLe and sense node S0 maintains a precharged level (e.g., 0.8 volts). If, during the develop period, the programming state of the selected memory cell is erased (i.e., the selected memory cell is erased, or ON), then the voltage apparent on selected bitline BLe and sense node S0 falls to a logic low level.

The level of the voltage apparent on sense node S0 after the develop period is used to verify whether a selected memory cell is ON or OFF (i.e., is programmed or erased). In accordance with an embodiment of the invention, latch circuit 260 controls latch 212 such that the logic value apparent on latch node D0 is “0” when the level of the voltage apparent on sense node S0 after the develop period is a logic high level (e.g., is equal to a precharge level). When the logic value apparent on latch node D0 is “0,” page buffer 200 is set to a programming operation mode. If the level of the voltage apparent on sense node S0 after the develop period is a logic low level, then the logic value apparent on latch node D0 is maintained at “1,” as it was set initially.

Sense and latch unit 260 comprises a latch 212 adapted to store data read during a normal read operation or a copyback read operation, and data to be programmed. Latch 212 comprises two inverters that output opposite data values relative to one another (i.e., the two inverters are set to complementary data values). Latch nodes D0 and nD0 are respectively disposed at output ports of the two inverters. During the normal read and copyback read operations, latch 212 is initially set (i.e., initialized) such that a logic value of “0” is apparent on latch node nD0 and a logic value of “1” is apparent on latch node D0. If a latch control signal LCH<7:0> is activated to a logic high level, the respective logic values apparent on latch nodes D0 and nD0 selectively change in response to the voltage level apparent on sense node S0. Whether or not they are changed, the logic values apparent on latch nodes D0 and nD0 are complementary. Control signal LCH<7:0> is activated to a logic high level during sense periods of normal read operations and copyback read operations. For example, if the level of the voltage apparent on sense node S0 is a logic high level (e.g., is equal to a precharge level) when control signal LCH<7:0> is activated to a logic high level, latch node D0 is discharged to a ground level through transistors 202, 203, and 204, which are all turned ON. As a result, a logic value of “0” is apparent on latch node D0. On the other hand, if the level of the voltage apparent on sense node S0 is a logic low level when control signal LCH<7:0> is activated to a logic high level, the logic value apparent on latch node D0 remains “1” because NMOS transistor 203 is OFF (i.e., the voltage apparent on sense node S0 does not turn NMOS transistor 203 ON). When the logic value apparent on latch node D0 remains “1,” the logic value apparent on latch node nD0 is “0”.

An NMOS transistor 211 is disposed between latch node D0 and sense node S0, and is adapted to provide a logic value (i.e., data) apparent on latch node D0 (i.e., data stored in latch 212) to selected bitline BLe in response to a control signal C11. Control signal C11 is activated during a programming period, during which data stored in latch 212 is transferred to bitline BLe. If the logic value apparent on latch node D0 is “1” during a programming operation (or programming operation of a copyback operation), the programming operation is inhibited. Therefore, latch 212 is initialized such that the logic value apparent on latch node D0 is “1”, as will be described below. As a result, the logic value apparent on latch node D0 may be “0” if the sensed memory cell is programmed (i.e., is OFF). Such an initial value setting for latch 212 is commonly applied in the normal read and copyback read operations.

A source of NMOS transistor 202 is connected to latch node D0, and a source of NMOS transistor 201 is connected to latch node nD0. NMOS transistor 202 provides a sense path in response to a control signal C2 during a read operation. Control signal C2 is activated to a logic high level during sense periods of the normal read operation and the copyback read operation. In response to control signal C1, NMOS transistor 201 initializes latch 212 such that the logic values apparent on latch nodes nD0 and D0 are “0” and “1,” respectively. Control signal C1 is activated to a logic high level during a page buffer setting period to initialize latch 212.

Drains of NMOS transistors 201 and 202 are each connected to a source of an NMOS transistor 206. NMOS transistor 206 is turned ON and OFF in response to a control signal DI0<7:0>. Control signal DI0<7:0> is activated to a logic high level when latch 212 is initialized (i.e., during a page buffer setting period) and when stored data D is output. NMOS transistors 203 and 204 are serially connected to terminals of NMOS transistors 201 and 202, and NMOS transistor 206. NMOS transistor 204 is turned ON during sense periods of the normal read operation and the copyback read operation in response to a control signal LCH<7:0>. In addition, NMOS transistor 203 is selectively turned ON during the sense periods. For example, if the level of the voltage apparent on sense node S0 is a logic high level (i.e., a selected memory cell is programmed, or OFF) during a sense period, NMOS transistor 203 is turned ON. If the level of the voltage apparent on sense node S0 is a logic low level (i.e., the selected memory cell is erased, or ON) during the sense period, NMOS transistor 203 is turned OFF.

Table 1 shows the respective operational states (i.e., ON or OFF) of the transistors of page buffer 200 illustrated in FIG. 2 and the logic states (i.e., high (H) or low (L)) of their respective control signals during periods of a read operation. Table 2 shows the operational state of NMOS transistor 203 illustrated in FIG. 2 and the logic level apparent on latch node D0 illustrated in FIG. 2, which may change in accordance with the operational state of NMOS transistor 203, during periods of a read operation.

TABLE 1

| Transistor | Page Buffer | Precharge | Develop | Sense |
|---|---|---|---|---|
| (Control Signal) | Setting Period | Period | Period | Period |
| 201 (C1) | ON (H) | OFF (L) | OFF (L) | OFF (L) |
| 202 (C2) | OFF (L) | OFF (L) | OFF (L) | ON (H) |
| 204 (LCH) | OFF (L) | OFF (L) | OFF (L) | ON (H) |
| 205 (LOAD) | OFF (H) | ON (L) | ON (L) | OFF (H) |
| 206 (DI0) | ON (H) | OFF (L) | OFF (L) | OFF (L) |
| 207 (BLSHF) | OFF (L) | ON (H) | OFF (L) | ON (H) |
| 208 (C8) | OFF (L) | ON (H) | ON (H) | ON (H) |
| 209 (C9) | OFF (L) | ON (H) | ON (H) | ON (H) |
| 210 (C10) | OFF (L) | OFF (L) | OFF (L) | OFF (L) |

TABLE 2

| | Transistor/ | Page Buffer | | | |
|---|---|---|---|---|---|
| | Latch | Setting | Precharge | Develop | Sense |
| | Node | Period | Period | Period | Period |
| Erased Cell | 203 | OFF | OFF | OFF | OFF |
| (ON Cell) | D0 | 1 | 1 | 1 | 1 |
| Programmed | 203 | OFF | OFF | OFF | ON |
| Cell | D0 | 1 | 1 | 1 | 0 |
| (Off Cell) | | | | | |

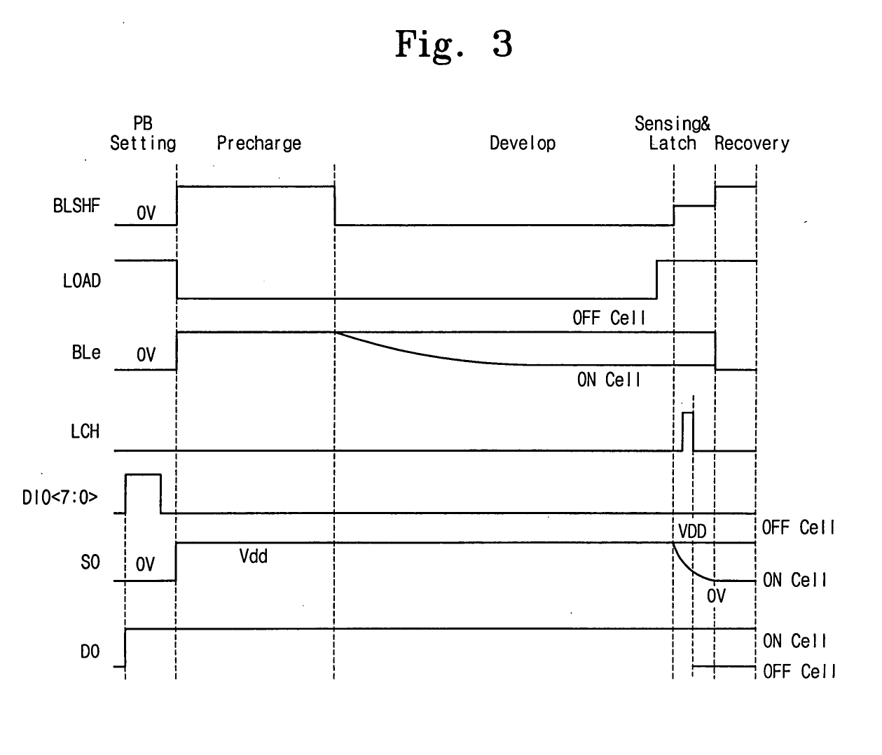

FIG. 3 is a timing diagram for an operation performed in page buffer 200 illustrated in FIG. 2. Specifically, FIG. 3 is a timing diagram for both a normal read operation and a copyback read operation performed in page buffer 200. Hereinafter, for convenience of description, the operation illustrated in FIG. 3 may be referred to simply as a “read operation.” The read operation performed in page buffer 200 will now be described with reference to Table 1, Table 2, FIG. 2, and FIG. 3.

As illustrated in FIG. 3, the entire read operation of page buffer 200 is divided into a page buffer setting period, a precharge period, a develop period, a sensing and latch period (which may also be referred to herein as a “sense period”), and a recovery period.

During the page buffer setting period, control signals C1 and DI0<7:0> are activated to a logic high level from a logic low level. NMOS transistors 201 and 206, which are associated with the initialization of latch 212, are turned ON in response to the activation of control signals C1 and DI0<7:0>. Consequently, during the page buffer setting period, latch 212 is initialized such that logic values “0” and “1” are apparent on latch nodes nD0 and D0, respectively.

When the precharge period begins, NMOS transistors 208 and 209 of bitline select and bias unit 220 are turned ON to select bitline BLe (i.e., selected bitline BLe) as the bitline that will be sensed during the sense period. In addition, PMOS transistor 205 and NMOS transistor 207 of precharge unit 240 are also turned ON so that sense node S0 and bitline BLe are each precharged by a power supply voltage VDD.

When the bitline develop period begins, shutoff control signal BLSHF, which is applied to the gate of NMOS transistor 207, is deactivated to a logic low level from a logic high level. Thus, the level of a voltage apparent on precharged bitline BLe may remain at a precharged level (i.e., a logic high level) or drop to a logic low level in accordance with whether the programming state of the selected memory cell (i.e., the corresponding memory cell) during the read operation is programmed or erased. For example, if the selected memory cell is programmed (i.e., is OFF), the level of the voltage apparent on bitline BLe remains at the precharged level. If the selected memory cell is erased (i.e., is ON), the level of the voltage apparent on bitline BLe drops to a logic low level during the develop period. While developing selected bitline BLe, a voltage level of precharge control signal LOAD, which is applied to PMOS transistor 205, is maintained at a logic low level, so PMOS transistor 205 remains ON. As a result, the level of the voltage apparent on sense node S0 is maintained at a precharge level. During the develop period, NMOS transistors 208 and 209 are also kept ON.

When the development of selected bitline BLe is completed, precharge control signal LOAD is changed from a logic low level to a logic high level (i.e., PMOS transistor 205 is turned OFF). Also, shutoff control signal BLSHF transitions from a logic low level to a logic high level. As a result, NMOS transistor 207 of precharge unit 240 is turned ON to apply a voltage apparent on selected bitline BLe (which may be referred to herein as developed selected bitline BLe) to a control gate of NMOS transistor 203 through NMOS transistors 207, 208, and 209. That is, the level of the voltage apparent on developed selected bitline BLe, which corresponds to the programming state of the selected memory cell, is sensed. If the voltage apparent on developed selected bitline BLe has a logic high level (i.e., the selected memory cell is programmed), NMOS transistor 203 is turned ON. If the voltage apparent on developed selected bitline BLe has a logic low level (i.e., the selected memory cell is erased), NMOS transistor 203 is turned OFF. At this point, latch signal LCH is activated to a logic high level for a short amount of time. As a result, NMOS transistor 204 is temporarily turned ON and the logic value apparent on latch node D0 is selectively changed in response to the level of the voltage apparent on developed selected bitline BLe.

If the voltage apparent on developed selected bitline BLe has a logic high level (i.e., the selected memory cell is programmed, or OFF) during the sensing and latch period, NMOS transistors 203 and 204 are each turned ON. Thus, a logic value apparent on latch node D0 changes from “1” to “0,” wherein latch 212 was initialized such that a logic value of “1” was apparent on latch node D0 initially. As a result, a logic value of “0” is apparent on latch node D0. If the voltage apparent on developed selected bitline BLe has a logic low level (i.e., the selected memory cell is erased, or ON) during the sensing and latch period, NMOS transistor 203 is turned OFF and NMOS transistor 204 is turned ON. Thus, an electrical path is not formed between latch node D0 and NMOS transistor 204. As a result, the logic value apparent on latch node D0 is maintained at its initially set logic value of “1,” so a logic value of “1” is apparent on latch node D0. The sensing and latch operation described above, which is performed in page buffer 200, is performed in both a normal read operation and a copyback read operation. As used herein, “storing a selected logic value in the latch” 212 is equivalent to maintaining or changing the logic value apparent on latch node D0 such that the selected logic value is apparent on latch node D0. Also, as used herein, language indicating that a logic value is “stored in the latch” 212 is equivalent to language indicating that the logic value is apparent on latch node D0.

As described above, page buffer 200 performs both a normal read operation and a copyback read operation along the same electrical path in page buffer 200. Therefore, since the logic value of data D (i.e., the logic value apparent on latch node D0) is the same during corresponding stages in a normal read operation and a corresponding copyback read operation, performing an inverse-read operation is not necessary. It is also unnecessary to perform a special operation for matching the respective logic values of data D stored during the normal read operation and a corresponding copyback read operation. As a result, controlling page buffer 200 is simplified. As used herein, a “corresponding copyback read operation” is a copyback read operation that corresponds to a normal read operation and that, if performed, would be performed on the same memory cell on which the corresponding copyback read operation is performed, wherein the memory cell would have the same programming state during the normal read operation and the corresponding copyback read operation.

As used herein, the term “unitary operation” should be construed broadly to include any operation adapted to perform either a normal read operation or a copyback read operation using a single page buffer. That is, the unitary operation is adapted to perform both the normal read operation and the copyback read operation on the same page buffer.

While bitline select and bias unit 220, precharge unit 240, and sense and latch unit 260 have been described in accordance with an embodiment of the invention, various modifications, changes, and substitutions thereof may be made without departing from the scope of the invention as defined by the accompanying claims. In particular, the foregoing configuration of sense and latch unit 260 adapted to sense a voltage level apparent on sense node S0 and latch a logic value in response to the sensed voltage level is merely illustrative and presented for the purpose of describing the invention. Accordingly, many modifications, substitutions, changes, and/or equivalents apparent to those skilled in the art may be made to sense and latch unit 260 (or used) without departing from the scope of the invention as defined by the accompanying claims.

What is claimed is:

1. A reading method comprising:
a unitary operation, the unitary operation adapted to execute either a normal read operation or a copyback read operation using a page buffer, the unitary operation comprising:
initializing a latch to store a first logic value;
sensing a voltage level corresponding to a programming state of a selected memory cell; and,
selectively storing a second logic value in the latch in response to the sensed voltage level,
wherein the page buffer enters a programming operation mode when the second logic value is stored in the latch.

2. The method of claim 1, wherein selectively storing the second logic value in the latch in response to the sensed voltage level comprises storing the second logic value in the latch if the sensed voltage level is a first voltage level, wherein the first voltage level indicates that the selected memory cell is programmed.

3. The method of claim 1, wherein selectively storing a second logic value in the latch in response to the sensed voltage level comprises continuing to store the first logic value in the latch if the sensed voltage level is a first voltage level, wherein the first voltage level indicates that the selected memory cell is erased.

4. The method of claim 1, wherein, in each of the normal read operation and the copyback read operation, selectively storing the second logic value in the latch in response to the sensed voltage level comprises selectively storing the second logic value in the latch in response to the sensed voltage level using a first electrical path of the page buffer.

5. The method of claim 1, wherein the latch stores the same logic value at corresponding stages of the normal read operation and a corresponding copyback read operation.

6. The method of claim 1, wherein the page buffer enters a program-inhibit operation mode when the first logic value is stored in the latch.

7. A method for performing a copyback read operation in a page buffer comprising:
initializing a latch to store a first logic value;
sensing a voltage level corresponding to a programming state of a selected memory cell; and,
selectively storing a second logic value in the latch in response to the sensed voltage level,
wherein the page buffer enters a programming operation mode when the second logic value is stored in the latch.

8. The method of claim 7, wherein selectively storing the second logic value in the latch in response to the sensed voltage level comprises storing the second logic value in the latch if the sensed voltage level is a first voltage level, wherein the first voltage level indicates that the selected memory cell is programmed.

9. The method of claim 7, wherein selectively storing the second logic value in the latch in response to the sensed voltage level comprises continuing to store the first logic value in the latch if the sensed voltage level is a first voltage level, wherein the first voltage level indicates that the selected memory cell is erased.

10. The method of claim 7, wherein the page buffer enters a program-inhibit operation mode when the first logic value is stored in the latch.

11. A page buffer adapted to perform either a normal read operation or a copyback read operation using a unitary operation, the page buffer comprising:
a bitline select and bias unit adapted to select a bitline corresponding to a selected memory cell;
a precharge unit adapted to precharge the bitline; and,
a sense and latch unit adapted to sense a level of a voltage apparent on the bitline and store a logic value in a latch in response to the sensed voltage level,
wherein the latch is initialized to store a first logic value during each of the normal read operation and the copyback read operation; and,
wherein the value stored in the latch changes from the first logic value to a second logic value if the sensed voltage level indicates that the selected memory cell is programmed.

12. The page buffer of claim 11, wherein the page buffer enters a program-inhibit operation mode when the first logic value is stored in the latch.

13. The page buffer of claim 11, wherein the page buffer enters a programming operation mode when the second logic value is stored in the latch.

14. The page buffer of claim 11, wherein, in each of the normal read operation and the copyback read operation, the page buffer is adapted to store logic values in the latch using a first electrical path of the page buffer.

15. The page buffer of claim 11, wherein the latch stores the same logic value at corresponding stages of the normal read operation and a corresponding copyback read operation.

16. The page buffer of claim 11, wherein the sense and latch unit is adapted to continue storing the first logic value in the latch if the sensed voltage indicates that the selected memory cell is erased.
